(19) United States
(12) Patent Application Publication
(10) Pub. No.: US 2008/0314443 A1
(43) Pub. Date: Dec. 25, 2008

(54) BACK-CONTACT SOLAR CELL FOR HIGH POWER-OVER-WEIGHT APPLICATIONS

(76) Inventors: Christopher Michael Bonner, Menlo Park, CA (US); Peter Cousins, Menlo Park, CA (US); Denis De Ceuster, Woodside, CA (US)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/143,556

(22) Filed: Jun. 20, 2008

Related U.S. Application Data
(60) Provisional application No. 60/936,954, filed on Jun. 23, 2007.

(51) Int. Cl. H01L 31/00

(52) U.S. Cl. 136/255

(57) ABSTRACT

A solar cell is described. The solar cell is fabricated on a substrate, the substrate having a front surface and a back surface. The substrate includes, at the front surface, a first region having a first global thickness and a second region having a second global thickness. The second global thickness is greater than the first global thickness. A plurality of alternating n-type and p-type doped regions is disposed at the back surface of the substrate.

### CROSS REFERENCE TO RELATED APPLICATIONS

This application claims the benefit of U.S. Provisional Application No. 60/936,954, filed Jun. 23, 2007, the entire contents of which are hereby incorporated by reference herein.

### TECHNICAL FIELD

Embodiments of the present invention are in the field of Semiconductor Fabrication and, in particular, Solar Cell Fabrication.

### BACKGROUND

Photo voltaic cells, commonly known as solar cells, are well known devices for direct conversion of solar radiation into electrical energy. Referring to FIG. 1, a solar cell 100 is fabricated on a wafer or substrate 102 of semiconductor material, generally silicon, using semiconductor processing techniques to form a number of p-doped and n-doped regions 104 and 106, respectively. Solar radiation impinging on a surface 108 of the substrate 102 creates electron and hole pairs in the bulk of the substrate, which migrate to p-doped and n-doped regions 104 and 106 in the substrate, thereby generating a voltage differential between the doped regions. Doped regions 104 and 106 are covered by a dielectric layer 110, and, in the embodiment shown, coupled to metal backside contacts 112 to direct an electrical current from solar cell 100 to an external circuit (not shown) coupled thereto. Typically, the surface 108 of solar cell 100 is textured and/or coated with a layer or coating of an antireflective material 114 to decrease the reflection of light and increase the efficiency of the cell.

After processing to fabricate solar cell 100, substrate 102 has a thickness of about 200 microns (μm), and a silicon weight of at least about 0.047 grams per square centimeter (47 mg/cm²). While this thickness is often desirable and even necessary to provide mechanical or structural strength to the solar cell, particularly in a location where output terminals of the cell are tab soldered to an external circuit, the weight can simply be too great relative to the power generated for many weight critical applications.

### BRIEF DESCRIPTION OF THE DRAWINGS

FIG. 1 is an illustration representing a cross-sectional side view of a conventional back-contact solar cell.

FIG. 2 is an illustration representing a cross-sectional side view of a waffle back-contact solar cell, in accordance with an embodiment of the present invention.

FIG. 3A is an illustration representing a planar top view of a solar cell having raised ridges separating the thinned regions and arranged to form patterns on a surface of the solar cell, in accordance with an embodiment of the present invention.

FIG. 3B is an illustration representing a perspective view of a cross-section of the solar cell of FIG. 3A, taken along the line 3B-3B, in accordance with an embodiment of the present invention.

FIG. 4 is an illustration representing a planar top view of a solar cell having off-axis planes, in accordance with an embodiment of the present invention.

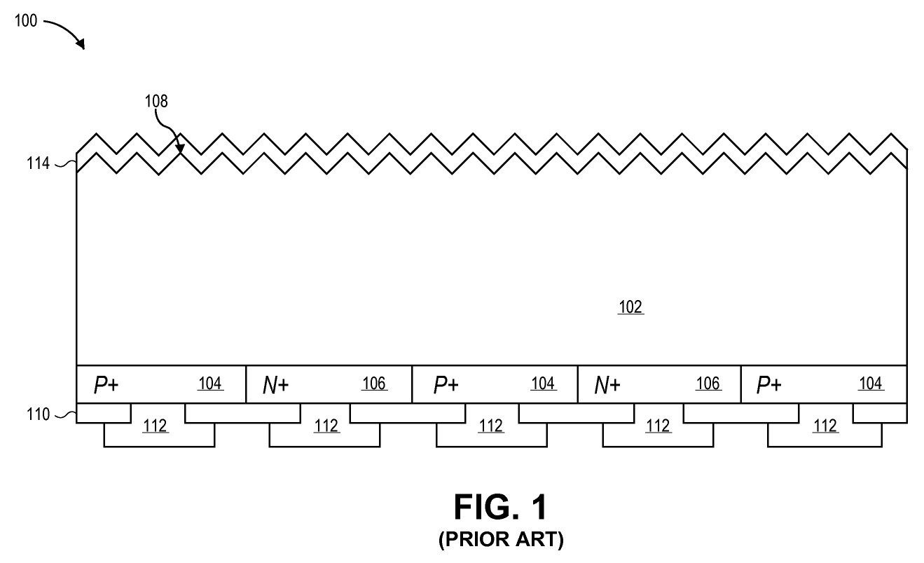

### DETAILED DESCRIPTION

A solar cell and methods to fabricate a solar cell are described herein. In the following description, numerous specific details are set forth, such as specific dimensions, in order to provide a thorough understanding of the present invention. It will be apparent to one skilled in the art that the present invention may be practiced without these specific details. In other instances, well-known processing steps, such as patterning steps, are not described in detail in order to not unnecessarily obscure the present invention. Furthermore, it is to be understood that the various embodiments shown in the Figures are illustrative representations and are not necessarily drawn to scale.

Reference in the description to “one embodiment” or “an embodiment” means that a particular feature, structure, or characteristic described in connection with the embodiment is included in at least one embodiment of the invention. The appearances of the phrase “in one embodiment” in various places in the specification do not necessarily all refer to the same embodiment.

The present invention is directed to a waffle back-contact solar cell and a method or process for fabricating the same. Such a solar cell may exhibit an increased power to weight ratio with respect to a conventional solar cell. In accordance with an embodiment of the present invention, a solar cell includes a number of thinned first regions having a first thickness and a number of raised second regions having a second thickness greater than the first thickness. In an embodiment, the raised second regions include a number of raised ridges separating the first regions, which are regularly spaced to form a pattern on a surface of the substrate used to form the solar cell. In a specific embodiment, at least some of the raised ridges intersect to form a waffle pattern on the surface of the substrate.

In an aspect of the invention, a front surface of a solar cell may be etched off locally, e.g. partially removed, to a predetermined depth or extended locally, e.g. partially grown or deposited on, to a predetermined height to provide a solar cell having a number of thin membranes in first regions and a number of raised ridges in second regions, separating and surrounding the first regions. In an embodiment, the edges or perimeter of the solar cell can be left thick to strengthen the solar cell, preventing crack formation at the solar cell edge and making the solar cell easier to fabricate and handle without risk of breakage. Additionally, the location where the solar cell will eventually be soldered can also be left thick, so the pressure caused by a tab soldering process will be applied to a thick, solid part of the cell. In one embodiment, the back surface of the solar cell is left flat so it does not unnecessarily complicate the patterning or etching process used to form the first and second regions. In accordance with an embodiment of the present invention, the solar cell is a back-contact solar cell to which contacts or connections to p-doped and n-doped regions of the cell are made at the back or lower surface of the cell.

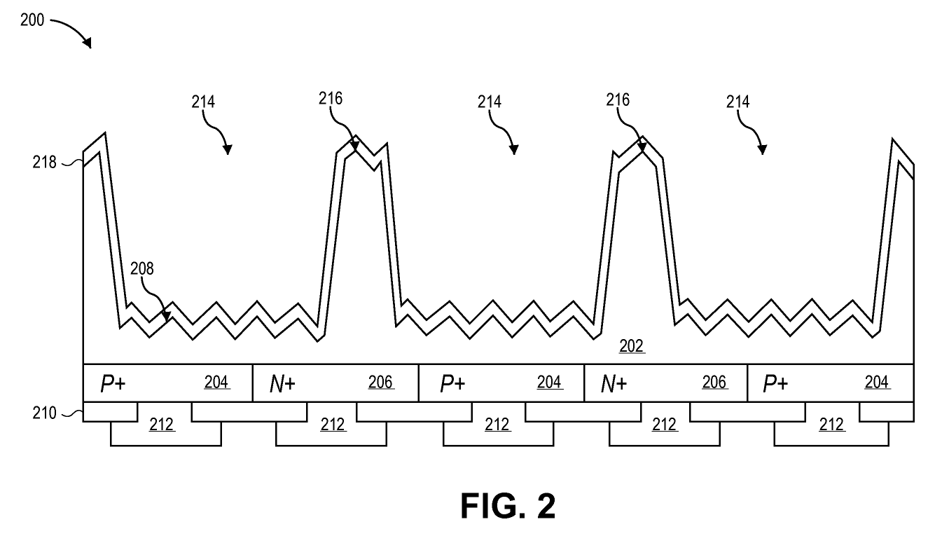

A solar cell may be fabricated to have regions of varying thickness. FIG. 2 is an illustration representing a cross-sectional side view of a waffle back-contact solar cell, in accordance with an embodiment of the present invention

Referring to FIG. 2, a solar cell 200 is fabricated on a substrate 202, the substrate having a front surface and a back surface. Substrate 202 includes first regions 214 at the front surface, the first regions having a first global thickness. Substrate 202 also includes second regions 216 at the front surface, the second regions having a second global thickness greater than the first global thickness. A plurality of alternating n-type 206 and p-type 204 doped regions are disposed at the back surface of substrate 202. The top surface of substrate 202 may have an intentionally roughened surface to maximize surface area collection of radiation and minimize reflection. Thus, in one embodiment, first regions 214 have a varying thickness across their surfaces, as depicted in FIG. 2. However, the global thickness of first regions 214 is determined to be the average thickness of first regions 214 as measured from the back surface of substrate 202. Similarly, in one embodiment, second regions 216 have a varying thickness across their surfaces, as is also depicted in FIG. 2. However, the global thickness of second regions 216 is determined to be the average thickness of the second regions 216 as measured from the back surface of substrate 202.

Substrate 202 may be composed of a semiconductor material such as, but not limited to, silicon, in which a number of p-doped and n-doped regions 204 and 206, respectively, have been formed. Solar radiation impinging on a surface 208 of substrate 202 creates electron and hole pairs in the bulk of substrate 202, which migrate to the p-doped and n-doped regions 204 and 206, generating a voltage differential between these doped regions. In one embodiment, the doped regions 204 and 206 are covered by a dielectric layer 210 such as, but not limited to, a silicon-dioxide (SiO₂) layer. Furthermore, in the embodiment shown, the doped regions 204 and 206 are coupled to metal backside contacts 212 to direct an electrical current from solar cell 200 to an external circuit (not shown) coupled thereto.

In an embodiment, as depicted in FIG. 2, solar cell 200 further includes an antireflective coating (ARC) layer 218 such as, but not limited to, one or more layers of material such as silicon nitride (SiN), silicon dioxide (SiO₂) or titanium oxide (TiO₂). ARC layer 218 overlies the top surface 208 of substrate 202 to further increase the solar radiation collection efficiency of the solar cell. As pointed out above, interleaved or interdigitated backside metal contacts 212 to the P+ and N+ regions 204, 206 may also be included and can be formed using standard lithographic, etching and metal deposition techniques. Backside contacts or back-contact solar cells and methods for forming the same are disclosed, for example, in U.S. Pat. Nos. 5,053,083 and 4,927,770, which are incorporated herein by reference in their entirety.

In accordance with an embodiment of the present invention, portions of first regions 214 and portions of second regions 216 alternate to provide a waffle pattern on the top surface of substrate 202, as depicted in FIG. 2. In an embodiment, the waffle pattern is aligned with a crystal orientation of substrate 202. In another aspect, the plurality of alternating n-type and p-type doped regions 206 and 204 may be arranged in substrate 202 according to the location of first regions 214 and second regions 216. In one embodiment, the plurality of alternating n-type and p-type doped regions 206 and 204 is aligned to have the n-type doped regions 206 overlapped by second regions 216, as depicted in FIG. 2. However, in an alternative embodiment, the plurality of alternating n-type and p-type doped regions 206 and 204 is aligned to have the p-type doped regions 204 overlapped by second regions 216. In yet another alternative embodiment, the plurality of alternating n-type and p-type doped regions 206 and 204 are not aligned with first regions 214 or second regions 216. The widths of portions of second regions 216 may vary, depending on structural requirements of solar cell 200. In accordance with an embodiment of the present invention, second regions 216 include a plurality of wide ridges separated by a plurality of narrower ridges. In one embodiment, the plurality of wide ridges includes ridges abutting a perimeter of solar cell 200 to strengthen solar cell 200. In an embodiment, the surface area of first regions 214 constitutes about 50 to about 90% of the total top surface area of solar cell 200. In an embodiment, the thickness of first regions 214, e.g. the first global thickness, is about 10 to about 50% of the second global thickness. In another embodiment, the global thickness of first regions 214 is about 80 microns, while the global thickness of second regions 216 is about 165 microns. It is to be understood that the back surface of substrate 202 need not be flat. That is, although not depicted, in accordance with another embodiment of the present invention, second regions 216 protrude past the back surface of first region 214.

To achieve a global thickness difference between first regions 214 and second regions 216, portions of substrate 202 may be etched. Thus, in accordance with an embodiment of the present invention, the front or top surface 208 of solar cell 200 is locally etched or patterned to a predetermined depth to form a number of thin membranes or thinned first regions 214 and a number of raised ridges in second regions 216, which separate and surround the first regions 214. In one embodiment, the local patterning is performed by first forming a patterned etch mask over the front surface 208 of substrate 202. Those areas of the front surface 208 of substrate 202 exposed by the patterned etch mask are etched to form thinned first regions 214. In that embodiment, areas of the front surface 208 of substrate 202 protected by the patterned etch mask are preserved to form second regions 216.

The local thinning or etch process may be accomplished by forming a patterned etch mask (not shown) on the top surface 208 of substrate 202, and subsequently etching the surface in a wet etch process using, for example, potassium hydroxide (KOH), sodium hydroxide (NaOH) or another anisotropic etch solution. In an embodiment, the etch mask includes one or more layers of materials, such as SiO₂ or silicon nitride (SiN), which is resistant to etching by the above etch solutions. The SiO₂ or SiN etch mask can be formed or deposited by any suitable technique including, for example, by thermally growing in a low pressure (100-200 mTorr) oxygen containing atmosphere or by chemical vapor deposition (CVD), and can be patterned using standard lithographic and etching techniques. The thickness of the SiO₂ or SiN etch mask or layer is selected to be sufficiently thick to protect and leave substantially un-etched areas of the substrate to form the raised second regions 216. Optionally, in one embodiment, the thickness of the SiO₂ or SiN etch mask is chosen such that the etch mask is substantially entirely consumed by the end of the local etch step, thereby eliminating the need for a separate strip or removal step. This may be possible because SiO₂ and SiN are etched by the etch solution, although at a much slower rate than the exposed silicon of substrate 202.

The etch process may be allowed to proceed for predetermined time or until substrate 202 has been thinned by a desired amount. It has been found that thinning substrate 202 by from about 50 to about 90% provides a desired reduction in the weight of solar cell 200. Similarly, the pattern and size of features in the etch mask, that is the separation between second regions 216 and width of each region, can be adjusted to optimize the solar cell mechanical properties, efficiency and weight. It has been found that these properties are optimized when the cumulative area of the thinned first regions 214 comprises about 50 to about 90% of a total surface area of solar cell 200 or the second regions 216 comprise a cumulative area of from about 10 to about 50% of solar cell 200. For example, in one embodiment, the thinned first regions 214 comprise about 75% of the total surface area of solar cell 200 and have a thickness of about 25% of that of the 200 μm thick un-etched second regions 216, for a thickness of about 50 microns. It has been found that these dimensions may reduce the weight of substrate 202 from about 0.047 grams per square centimeter (47 mg/cm²) to about 0.020 g/cm².

Finally, the etch mask is stripped or removed using any suitable means including, for example, wet or dry etching or chemical mechanical polishing (CMP). In one embodiment, the etch mask is removed in a wet etch process utilizing a hydrofluoric acid (HF) containing solution. Alternatively, the etch mask may be left to remain on the finished solar cell 200 since, given the small surface area of the second regions 216, any loss in efficiency of the cell may be offset by the lower fabrication cost and increased power to weight ratio.

In an embodiment, after the top surface 208 of solar cell 200 is locally etched to form first and second regions 214 and 216, respectively, top surface 208 is textured in a wet etch process using potassium hydroxide (KOH) and isopropyl alcohol (IPA) or other anisotropic etch solutions to form random features, such as the pyramids shown in FIG. 2. In one embodiment, such texturing improves the solar radiation collection efficiency of solar cell 200. Alternatively, the top surface 208 of substrate 202 may be textured or patterned using standard lithographic and etching processes to form regular repeating features or a pattern. Advantageously, the dielectric (SiO₂) layer 210 may serve to protect the P+ and N+ regions 204 and 206 during the texturing etch or processes. In one embodiment, the texturing may be accomplished prior to the removal of the etch mask, in which case only the first regions 214 will be textured, while the raised second regions 216 maintain a substantially planar surface.

In another aspect of the present invention, a growth process may be used in place of an etch process. That is, to achieve a global thickness difference between first regions 214 and second regions 216, portions of substrate 202 may be extended in a growth or deposition process. Thus, in accordance with an embodiment of the present invention, material is locally deposited or grown on the front or top surface 208 of solar cell 200 to a predetermined thickness to form a number of thick or raised ridges, e.g. to form second regions 216, separating and surrounding thinner first regions 214. In one embodiment, the local patterning is performed by first forming a patterned mask over the front surface 208 of substrate 202. Those areas of the front surface 208 of substrate 202 exposed by the patterned mask are extended to form thickened second regions 216. In that embodiment, areas of the front surface 208 of substrate 202 protected by the patterned mask are preserved to form first regions 214. In an embodiment, the areas of the front surface 208 of substrate 202 exposed by the patterned mask are extended by a selective growth or deposition process. In a specific embodiment, the areas of the front surface 208 of substrate 202 exposed by the patterned mask are extended by a selective chemical vapor deposition process that forms an epitaxial layer on exposed portions of a silicon substrate 202, but not on the patterned mask.

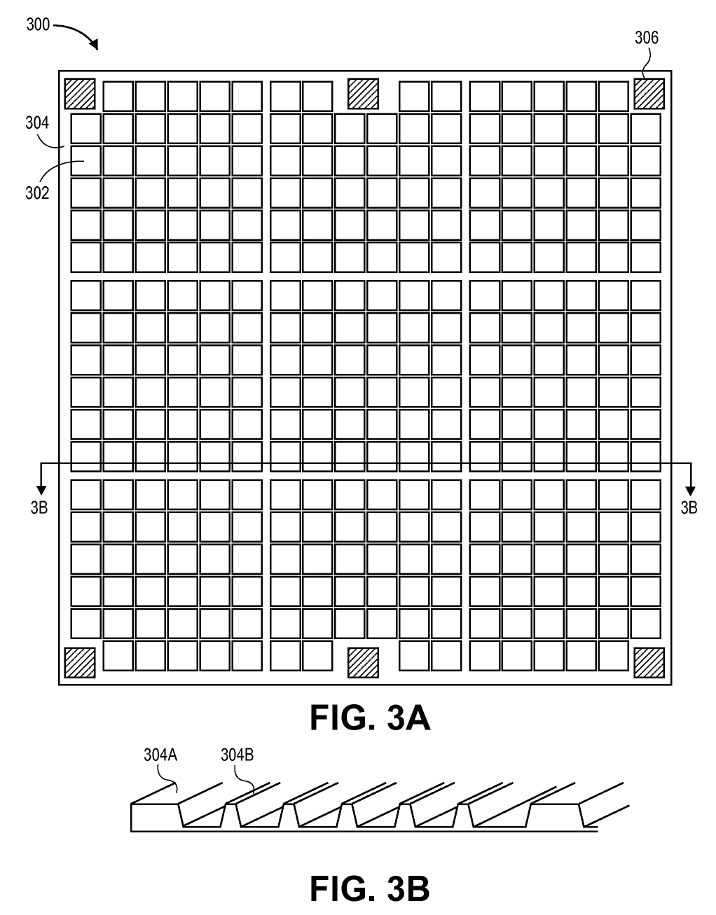

Patterns formed on the top surface of a solar cell by raised ridges of the second regions and the thinned first regions are described with reference to FIGS. 3A and 3B, in accordance with an embodiment of the present invention.

Referring to FIG. 3A, the top surface of a solar cell 300 is locally patterned, e.g. by an etch process or by a growth or deposition process, to form a number of polygonal shaped first regions 302 separated by a number of second regularly shaped and spaced intersecting ridges or raised regions 304. In an alternative embodiment, not depicted, first regions 302 have a box shape with relatively straight sidewalls as opposed to having a polygonal shape. In either case, the arrangement forms a pattern having a waffle or waffle-like appearance as shown. In one embodiment, as depicted in FIG. 3B, the top surface of solar cell 300 is locally patterned to form a number of wide ridges or raised regions 304A interspersed with or separated by a larger number of narrower ridges 304B. In a specific embodiment, the narrow ridges or raised regions 304B have a width that is from about 25% to about 150% of the thickness of the un-etched substrate of solar cell 300, while the wide ridges 304A have a width that is from about 10 to about 100 times greater than the narrow ridges. In another specific embodiment, the narrow ridges 304B have a width of from about 100 to about 200 microns, while the wide ridges 304A have a width of about 1 centimeter.

As noted above, solar cell 300 can further include a number of soldering tabs or pads 306 in the raised or un-etched regions near the perimeter, so that the pressure caused by a tab soldering process will be applied to a thick, solid part of the cell. In other embodiments, not shown, the top surface of the solar cell is etched to form a number of first regions separated by a number of regularly shaped and spaced non-intersecting ridges or second regions. In one version of this non-intersecting embodiment, the ridges or second regions comprise concentric rings defining a number of circular and ring shaped first regions therebetween. In a specific embodiment, the ridges or second regions further include at least one ridge or raised region abutting a perimeter or edge of the solar cell to strengthen the solar cell.

The advantages of the solar cell and fabricating method of the present invention over previous or conventional cells and methods include: (i) a substantial reduction in solar cell weight without detrimentally impacting the structural strength and integrity of the cell; (ii) increased power to weight ratio of the solar cell; and (iii) compatibility with existing solar cell manufacturing processes and equipment. In addition, it has been found that reducing the thickness of the substrate in the first regions desirably reduces degradation in cell efficiency due increases in temperature.

In an additional aspect of the present invention, thicker regions of a substrate used in a solar cell may be removed following completion of the fabrication of the solar cell. That is, in accordance with an embodiment of the present invention, thicker regions are included during the fabrication of a solar cell in order to provide structural integrity for the solar cell during fabrication. Then, once the need for the structural integrity is diminished, part or all of the thicker region or regions can be removed to provide an even lighter weight solar cell. In one embodiment, a portion of the thicker second regions are removed subsequent to forming the plurality of alternating n-type and p-type doped regions. In a specific embodiment, a portion of the thicker second regions is aligned near or at the perimeter of the solar cell to facilitate slicing off that portion to reduce the contribution of thick regions to the overall weight of the final solar cell.

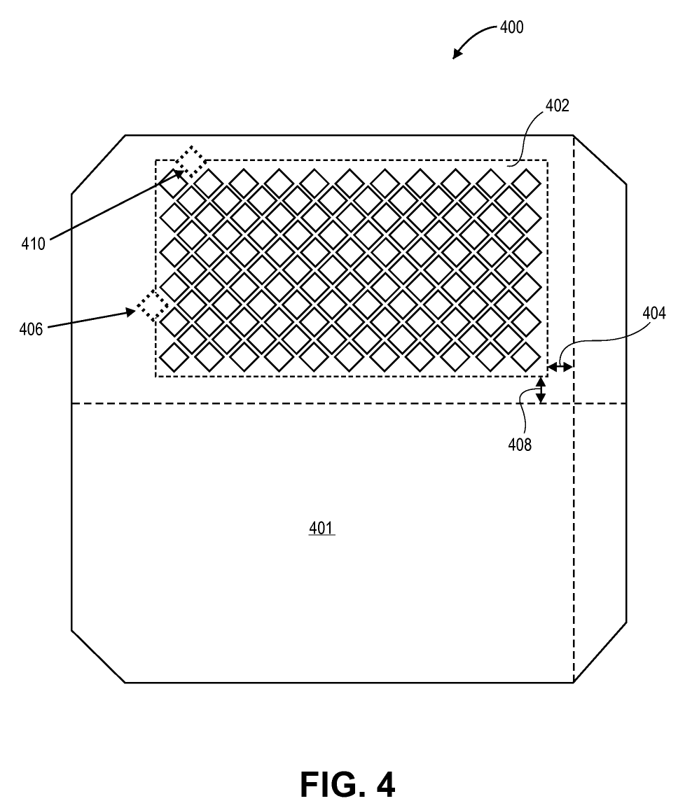

In an aspect of the invention, the thinned regions of a solar cell need not be aligned with the axes of the solar cell, as was depicted in FIG. 3A. Furthermore, the axes of the solar cell need not correspond to the crystal planes of the substrate of the solar cell. Instead, in accordance with another embodiment of the present invention, the thinned regions of a solar cell are arranged to be off-axis in relation to the axes of the solar cell. FIG. 4 is an illustration representing a planar top view of a solar cell having off-axis planes, in accordance with an embodiment of the present invention. Referring to FIG. 4, solar cell 400 is formed on a substrate 401 and has axes parallel with the dashed lines. However, the thinned regions, represented by the diamond shapes housed within region 402, are off-axis with respect to the axes of solar cell 400. In a specific embodiment, the thinned regions are off-axis by approximately 45 degrees, as depicted in FIG. 4. The off-axis thinned regions may be restricted to a particular region of substrate 401 of solar cell 400, e.g. region 402, depending on the spacing and structural requirements of solar cell 400. For example, in an embodiment, all thinned regions are restricted to region 402, as depicted in FIG. 4. However, in another embodiment, a first off-axis thinned region 406 is permitted to be formed to protrude from the left side of region 402, as depicted, or from the right side of region 402 to encroach on spacing 404. However, in a specific embodiment of that embodiment, a second off-axis thinned region 410 is not permitted to be formed to protrude from the top side of region 402, as depicted, or from the bottom side of region 402 to otherwise encroach on spacing 408. In an embodiment, the thickness of the substrate at the thinned regions is approximately in the range of 40-100 microns.

The foregoing description of specific embodiments and examples of the invention have been presented for the purpose of illustration and description, and although the invention has been described and illustrated by certain of the preceding examples, it is not to be construed as being limited thereby. They are not intended to be exhaustive or to limit the invention to the precise forms disclosed, and many modifications, improvements and variations within the scope of the invention are possible in light of the above teaching. It is intended that the scope of the invention encompass the generic area as herein disclosed, and by the claims appended hereto and their equivalents. The scope of the present invention is defined by the claims, which includes known equivalents and unforeseeable equivalents at the time of filing of this application.

1. A solar cell fabricated on a substrate, the substrate having a front surface and a back surface and comprising:
a first region at the front surface, the first region having a first global thickness;
a second region at the front surface, the second region having a second global thickness greater than the first global thickness; and
a plurality of alternating n-type and p-type doped regions disposed at the back surface.

2. The solar cell of claim 1, wherein portions of the first region and portions of the second region alternate to provide a waffle pattern on the front surface of the substrate.

3. The solar cell of claim 1, wherein the plurality of alternating n-type and p-type doped regions is aligned to have the n-type doped regions overlapped by the second region.

4. The solar cell of claim 1, wherein the plurality of alternating n-type and p-type doped regions is aligned to have the p-type doped regions overlapped by the second region.

5. The solar cell of claim 2, wherein the second region comprises a plurality of wide ridges separated by a plurality of narrower ridges.

6. The solar cell of claim 5, wherein the plurality of wide ridges comprises ridges abutting a perimeter of the solar cell to strengthen the solar cell.

7. The solar cell of claim 1, wherein the surface area of the first region comprises about 50% to about 90% of the total front surface area of the solar cell.

8. The solar cell of claim 1, wherein the first global thickness is about 10% to about 50% of the second global thickness.

9. A method of fabricating a solar cell, comprising:
providing a substrate having a front surface and a back surface;
forming a first region and a second region at the front surface of the substrate, the first region having a first global thickness and the second region having a second global thickness greater than the first global thickness; and
forming a plurality of alternating n-type and p-type doped regions at the back surface of the substrate.

10. The method of claim 9, wherein forming the first region and the second region comprises:
forming a patterned etch mask over the front surface of the substrate; and
etching, to form the first region, areas of the front surface of the substrate exposed by the patterned etch mask, wherein areas of the front surface of the substrate protected by the patterned etch mask are preserved to form the second region.

11. The method of claim 10, wherein the substrate comprises silicon, and wherein etching the front surface of the substrate comprises wet etching the front surface of the substrate in a solution comprising potassium hydroxide (KOH) or sodium hydroxide (NaOH).

12. The method of claim 9, wherein forming the first region and the second region comprises:
forming a patterned mask over the front surface of the substrate; and
extending, to form the second region, areas of the front surface of the substrate exposed by the patterned etch mask, wherein areas of the front surface of the substrate protected by the patterned mask are preserved to form the first region.

13. The method of claim 9, further comprising:
removing a portion of the second region subsequent to forming the plurality of alternating n-type and p-type doped regions.

14. The method of claim 9, wherein forming the first region and the second region comprises forming alternating portions of the first region and portions of the second region to provide a waffle pattern on the front surface of the substrate.

15. The method of claim 9, wherein forming the plurality of alternating n-type and p-type doped regions comprises aligning the n-type doped regions to be overlapped by the second region.

16. The method of claim 9, wherein forming the plurality of alternating n-type and p-type doped regions comprises aligning the p-type doped regions to be overlapped by the second region.

17. The method of claim 14, wherein forming the second region comprises forming a plurality of wide ridges separated by a plurality of narrower ridges.

18. The method of claim 17, wherein forming the plurality of wide ridges comprises forming ridges abutting a perimeter of the solar cell to strengthen the solar cell.

19. The method of claim 9, wherein the surface area of the first region comprises about 50% to about 90% of the total front surface area of the solar cell.

20. The method of claim 9, wherein the first global thickness is about 10% to about 50% of the second global thickness.
